(19) United States
(12) Patent Application Publication
(10) Pub. No.: US 2006/0012020 A1
(43) Pub. Date: Jan. 19, 2006

(54) Wafer-level assembly method for semiconductor devices

(76) Inventor: Kenneth B. Gilleo, Warwick, RI (US)

Correspondence Address: Kenneth Burton Gilleo, 38 Cedar Pond Drive, Unit 6, Warwick, RI, 02886, US

(21) Appl. No.: 11/177,741

(22) Filed: Jul. 8, 2005

Related U.S. Application Data
(60) Provisional application No. 60/587,588, filed on Jul. 14, 2004.

(51) Int. Cl. H01L 23/02

(52) U.S. Cl. 257/678

(57) ABSTRACT

A wafer-level assembly method for bonding chips to other wafers or to arrays of circuits. The method allows an array of chips, held on a temporary carrier, to be separated by expanding said carrier so that said chips can be aligned and bonded to a substrate with dimensions that would not otherwise permit registration of the chips.

### RELATED APPLICATIONS

This application claims the benefit of the following: U.S. Provisional Application No. US60/587,588 filed Jul. 14, 2004. The entire teachings of this patent application are incorporated herein by reference.

### FIELD OF INVENTION

The present invention relates to a novel wafer-level assembly method for simultaneously joining all of the integrated circuits contained in a wafer to devices on a second wafer, that can have dissimilar dimensions, to form die stacks useful for multichip modules, and in addition, allows an entire wafer of flip chips to be assembled to an array of printed circuits including, but not limited to, RFID tags.

### BACKGROUND OF THE INVENTION

Electronic semiconductor chips, or die, (devices for logic functions, memory, radio frequency, optoelectronics, etc.) are generally placed in component packages that are subsequently bonded to printed wiring boards for electronic communication therewith. Electronic packages by providing in several different formats: feed-through packages 12 (FIGS. 1 and 2), surface-mount packages 14 (FIGS. 3 and 4) and ball grid arrays 16 (FIGS. 5 and 6), most of which encapsulate a chip are overmolded with plastic. Packages normally contain a single chip, but they may contain more than one device and these are referred to as multichip packages. In the past, multiple chips were placed within a package on the same plane, side by side. More recently, multichip packages have been designed with chips placed one upon the other to form a die stack to reduce the length and width of the package base, or the package “footprint”. These newer multichip packages are generally designed as a ball grid array package 16 (FIGS. 7 and 8) and are referred to as stacked die, or 3-dimensional packages. The stacked-die packages have become popular because of the area reduction that they afford and the resulting miniaturization of the final product. Chips can be connected by thin bonding wires 24 (FIG. 7) or by combinations of wires 24 and flip chips 23 (FIG. 8).

Both feed-through and surface mount packages include metal leads 18 embedded in and extending from an epoxy molding compound 20; a chip 22 is also embedded in the epoxy molding compound 20 and coupled with the metal leads 18 via wires 24. The epoxy molding compound 20 fully surrounds and contacts the chip 22. The feed-through package 12 illustrated in FIGS. 1 and 2 is a dual in-line package (DIP). It differs from the surface-mount package 14 of FIGS. 3 and 4 in that the leads 18 of the feed-through package 12 are straight, allowing them to pass through a printed wiring board, whereas the leads 21 of the surface-mount package 14 are bent, allowing them to be bonded onto a proximate side of a printed wiring board.

A ball-grid array package 16, shown in FIGS. 5, 6, 7, and 8 includes a chip platform 26 having solder balls 28 mounted on one side of the chip platform 26 and having the chip 22, wires 24 and epoxy molding compound 20 on the other side of the chip platform 26. The chip 22 is bonded to the chip platform 26 via a layer of die paste (die attach adhesive) 29. Like the feed-through package 12 and surface-mount package 14, the ball-grid array 16 typically is overmolded with the epoxy molding compound 20, thereby leaving no cavity or free space around the encapsulated component (e.g., chip 22). Electronic communication between the chip 22 and the solder balls 28 is provided by copper patterns 30 on the surface of the chip platform 26, which can be in the form of a polyimide substrate, and conductive vias 32 extending through the chip platform 26.

Chips can also be directly bonded to the printed circuit board, or to a package platform by a process known as Direct Chip Attach (DCA) and also referred to as flip chip 23 (FIGS. 9 and 10). The direct chip attach process, developed in the mid-1960's, is well known to the industry and is widely practiced today. The flip chip can be bonded to the printed circuit board by soldering, by direct metal-to-metal fusion, or by employing conductive adhesive. The essential element of the flip chip is the bump that can be a solder ball 28 (FIGS. 9 and 10). The bump, or ball, is an elevated electrically conductive structure formed directly over the electrical connection pads of the chip. Bumps can be formed while the chips are still in wafer form and this method is preferred. The bumps can also comprise a non-fusible metal. However, the use of solder bumps permits the flip chip to be bonded to the printed circuit board, or other platform, by employing heat to reflow the solder and thus form a connecting joint 31 (FIG. 10). A flip chip with non-fusible bumps can be connected to a printed circuit board by adding a jointing material such as solder paste or conductive adhesive. The jointing material can be applied onto the flip chip bumps before the wafer is singulated into individual chips. Formation of structures, such as bumps, or the addition of materials to chips still in wafer format, is referred to as wafer-level processing.

Wafer-level processing has more recently become popular because processes such as bumping, can be performed simultaneously to provide superior economics. Entire packages have also been manufactured using a sequence of wafer-level processes and the technology is commonly known as wafer-level packaging. However, one major limit for this form of processing is that the package size must match physical dimensions of the chip; the package platform must be chip-size.

The size restriction is also a problem for stacked die multichip packaging. Prior art generally requires chips to have the same dimensions if they are to be combined, or stacked, using wafer-level processes. In most examples, the most stacked die prior art avoids wafer-level chip stacking and describe methods using individual die stacking. Many describe first singulating the wafer and then assemble the chips into the package in stepwise fashion. While this allows chips to be stacked, one on top of the other, the many benefits of wafer-level processing is lost.

A limited amount of prior art does describe stacking of chips at wafer-level. However, in order to bond chip wafers together, prior art requires that the chips of both wafers have the same physical dimensions. But the joining of such wafers in the normal face up configuration would obscure bonding pads for chips on all lower wafers and only the top wafer would be accessible to wire bonding or some other chip interconnect method.

Prior art has worked around this problem by bonding wafers back-to-back so that the respective interconnect on each chip face remain available for connection to a package. This concept limits the die stack to only two chips and requires complex packaging constructions to connect the chips that are positioned upward and downward. For example, Ball, in U.S. Pat. No. 5,952,725, discloses a method for increasing circuit density by stacking an upper wafer and a lower wafer, each of which have fabricated circuitry in specific areas on their respective face surfaces. The upper wafer is attached back to back with the lower wafer, with a layer of adhesive being applied on the back side of the lower wafer. The wafers are aligned to bring complimentary circuitry on each of the wafers into perpendicular alignment. The adhered wafer pair is then itself attached to an adhesive film to immobilize the wafer during dicing. The adhered wafer pair may be diced into individual die pairs or wafer portions containing more than one die pair.

Other die stacking methods add special electrical interconnection features so that the die stack may be electrically connected with all chips facing upward. The extra connections may be added to the back of the die or to the sides. Vias through the chip are a common solution. But all of these methods require added steps to the semiconductor process at a cost penalty. For example, U.S. Pat. No. 5,872,025 to Cronin et al discloses a stacked 3-dimensional device which is prepared by stacking wafers with special interconnection features. The chip regions are formed on the wafers to be combined with each chip region being surrounded by an insulator-filled trench. The wafers are then stacked with the chip regions in alignment and joined together by lamination. After laminating the stacks of wafers, stacks of chips are separated by etching, dicing or other processes.

None of these patents discloses the concept of increasing the spacing between smaller die for bonding to facilitate bonding to larger die by expanding an elastomeric wafer carrier tape. Even a patent that utilize expandable wafer tape failed to discover the concept of increasing spaces between individual die for stacking. In particular, U.S. Pat. No. 6,514,795 and U.S. Pat. No. 6,894,380 to Jiang, describe stretching, or expanding wafer tape, but the disclosed processes use carrier tape expansion to produce thinner layers of adhesive that are subsequently applied to chips. Jiang completely misses the basic concept of my invention, that of expanding wafer tape to spatially separate chips to enable joining to a second wafer having chips of a larger dimension. Jiang's use of expandable wafer tape, but failure to anticipate the invention that will be disclosed, is submitted as evidence that said invention is not obvious to one skilled in the art.

### SUMMARY OF THE INVENTION

Described, infra, are new wafer-level processes that can be applied to packages described as prior art and to direct chip assembly to substrate. These methods enable chips to be bonded to packages, substrates or to other wafers. A wafer typically contains a plurality of chips that are either square or rectangular to enable singulation into individual chips by sawing the wafer. A key feature of the method of this invention is that the array of chips can be simultaneously bonded to a substrate that is a different size.

The first step of the process of the invention is to temporarily affix a semiconductor wafer to an adhesive backed tape, or film. This is commonly done in semiconductor wafer processing. However, the tape of this invention is provided with an elastomeric base that allows for substantial expansion when outward tensional force is applied to the edges. The carrier can thus be expanded symmetrically in a controlled manner by the appropriate application of mechanical force. The wafer must first be sawn, or singulated, prior to expanding the carrier. Wafer singulation is a well-known process that has long been used by the semiconductor industry to convert a wafer array of devices into individual chips for packaging or direct attachment to a printed circuit board or other suitable substrate. The most common singulation method is mechanical sawing with a diamond saw, but other methods, such as laser singulation, are known and can be used within this invention. It is important to note that the singulation method does not cut, or otherwise damage the carrier tape.

The elastomeric carrier tape that contains singulated chips is now ready to be expanded so that the specific spacing between individual chips can be afforded. Any method for applying controlled tangential force to the perimeter of the carrier can be employed. Small grippers can be used to clamp the edges of the film, for example. Alternatively, a clamping ring can also be used. But regardless of the mechanical connection process, the apparatus must be capable of applying a well-controlled force to allow the desired expansion of the carrier tape. Various carrier expander mechanisms can be used, but this invention is not limited to particular method of producing carrier expansion.

The carrier can be symmetrically expanded to separate individual chips from one another so that they can be aligned with a symmetrical substrate that can have feature sizes that are larger than said chips. The substrate that is subsequently joined to the array of chips can comprise a corresponding array of packages, such as BGAs. The package substrate can remain in the array format commonly used for its production. The expanded carrier that holds the singulated chips is next accurately aligned, or registered, to the package array substrate. The two structures are then bonded together, or otherwise attached. The carrier is next removed, or de-bonded, from the chips. While pressure-sensitive tapes can be separated from chips by applying mechanical force, de-bondable tape is preferred so that the chips are not subjected to mechanical forces that could damage said chips or the interconnection that was made to the package. Ultraviolet, or UV, deactivated adhesives and tapes are well known to the industry and can be used here.

The expanded carrier that holds the singulated chips can also be bonded to another array of singulated chips affixed to conventional dicing tape. The wafers to be bonded can thus contain chips of different sizes. The elastomeric carrier is expanded until the desired spacing is obtained and then the two arrays of chips are bonded together using solder, adhesive paste, or film. The smaller chip can therefore be bonded to the larger chip so that the connection points, or bond pads, of the larger chip are not obscured by the smaller. This chip-to-chip configuration thus becomes the basis for stacked die multichip modules using ordinary wafers. The advantage is that a large number of chips are simultaneously bonded together instead of one at a time as is presently done. The process can be repeated so that a third chip is added to the stack. The stacking process can be repeated with progressively smaller chips until the desired die stack is achieved. The die stack is now ready to be bonded to a package by applying a die attach adhesive to the bottom die or to the package platform. The stack of die is then interconnected to the package by wire bonding. This process can thus produce the same multichip package products, now manufactured, with minimum labor compared to existing methods where die are singulated and individually stacked.

The process of my invention can also be used to directly attach chips to a printed circuit board or similar structure with appropriate interconnect features. One important application is for the production of Radio Frequency Identification products, also known as RFID tags. Present methods require that the chips are singulated and the bonded to the substrate that contain the antenna circuit. Said chips are generally connected to the antennas by direct chip attach that was described earlier. Since low cost but temperature-limited substrate is typically used, the jointing material is often a low temperature conductive adhesive. The adhesive can be in a paste or dry form that is heat activated and it can be applied to the bumps on the flip chips or onto the antenna circuit. But in all known cases, individual chips are bonded in singular fashion that adds to cost. One exception is a fluidic self-alignment process used by Alien Technology (Morgan Hill, Calif.) where chips are formed in a nonsymmetrical shape to fit into corresponding recesses in antenna circuits. While fluidic self-alignment allows more than one chip and antenna to be mated simultaneously, the method requires many added steps and reduces the cost savings of mass processing. The method may only be applicable to simple chips, especially RFID types. My method allows an entire wafer of chips to be bonded to an array of antennas without requiring any additional steps or special chip features so that the lowest total cost is achieved.

### BRIEF DESCRIPTION OF THE DRAWINGS

In the accompanying drawings, described below, like reference characters refer to the same or similar parts throughout the different views. The drawings are not necessarily to scale, emphasis instead being placed upon illustrating particular principles of the methods and apparatus characterized in the Detailed Description.

FIG. 1 is a perspective view of a dual in-line package.

FIG. 2 is a sectional view of the dual in-line package.

FIG. 3 is a sectional view of a quad surface-mount package.

FIG. 4 is a perspective view of the quad surface-mount package.

FIG. 5 is a perspective, cut-away view of a ball-grid-array package.

FIG. 6 is a sectional view of the ball-grid-array package.

FIG. 7 is a sectional view of a stacked-die multichip package using wire bonding.

FIG. 8 is a sectional view of a stacked-die multichip package using a flip chip.

FIG. 9 is a perspective view of a flip chip.

FIG. 10 is a sectional view of a flip chip assembled to substrate.

FIG. 11 is a topside view of a wafer.

FIG. 12A and 12B are topside views of a modified ring expander.

FIG. 13A is a perspective views of grippers for expanding carrier.

FIG. 13B is a top-view of a carrier expanded asymmetrically.

FIG. 14A is a sectional view of chips on carrier aligned to a wafer.

FIG. 14B is a sectional view of chips on carrier bonded to a wafer.

FIG. 14C is a sectional view of chip bonded to chip.

FIG. 15A is a sectional view of flip chips on carrier aligned to RFID circuits.

FIG. 15B is a sectional view of flip chips bonded to RFID circuits.

FIG. 15C is a sectional view of flip chip bonded to RFID circuits.

FIG. 16 is a prospective view of an RFID circuit with adhesive film showing a flip chip ready to be bonded.

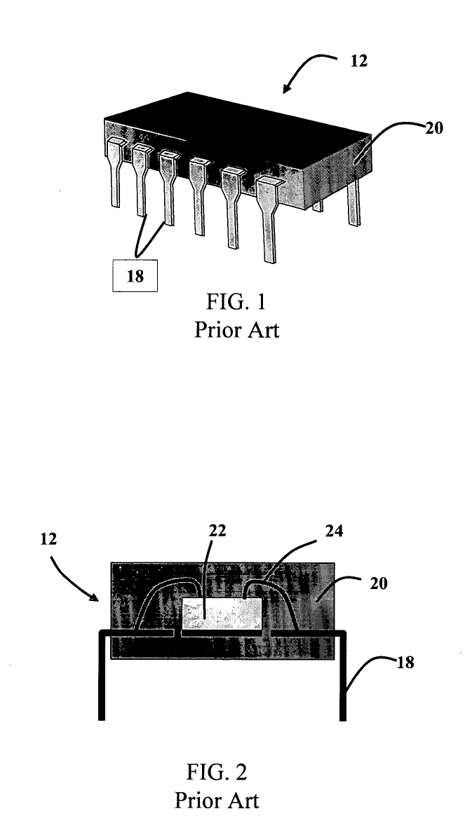

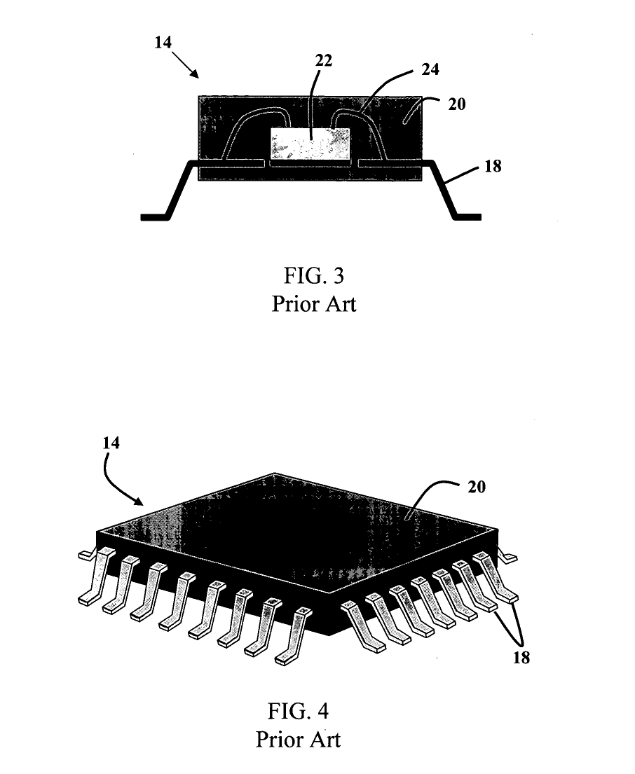

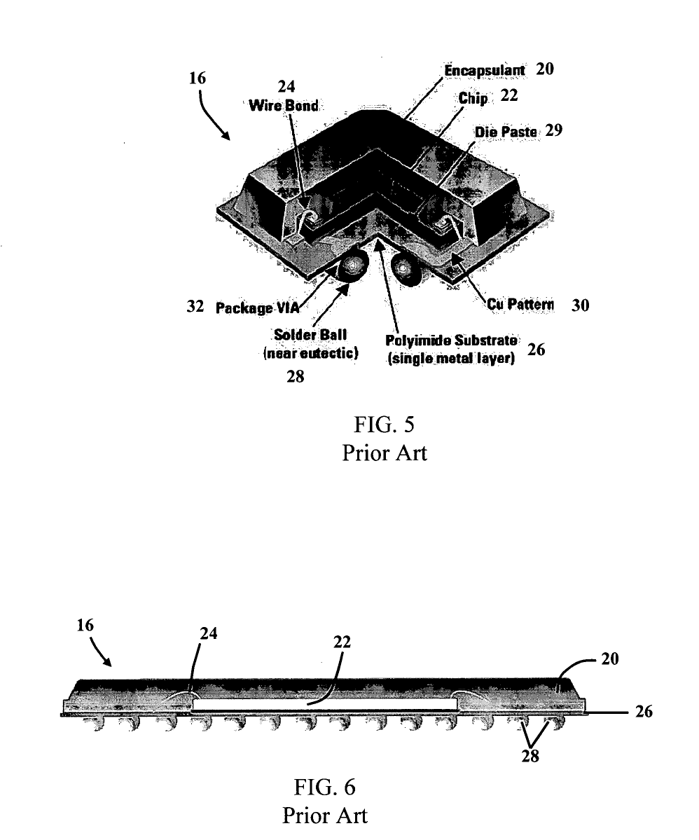

### DETAILED DESCRIPTION OF THE INVENTION

Described, infra, are novel wafer-level processes that can be used to economically manufacture chip assemblies for multichip modules, component packages, and chip-on-board products. These methods enable semiconductor chips to be simultaneously bonded to a plurality of single chip packages. The method can also be used to pre-assemble chips into a die stack prior to assembling them in a multichip package or module. The method can also be used to simultaneously bond chips to printed circuit boards to greatly reduce manufacturing cost. This can be especially advantageous for producing radio frequency identification products, such as RFID tags, that are extremely cost-sensitive. Unlike prior wafer-level processes, my method allows a plurality of chips to be simultaneously bonded to an array of chips, to packages, or to printed circuit boards. Furthermore, a wafer comprising a plurality of chips can be assembled to other chips, packages, circuits, and the like, that have greater dimensions than chips of said wafer. The ability to simultaneously join semiconductor devices to dissimilar dimensioned substrate provides a novel, low cost, greatly simplified process over all prior art.

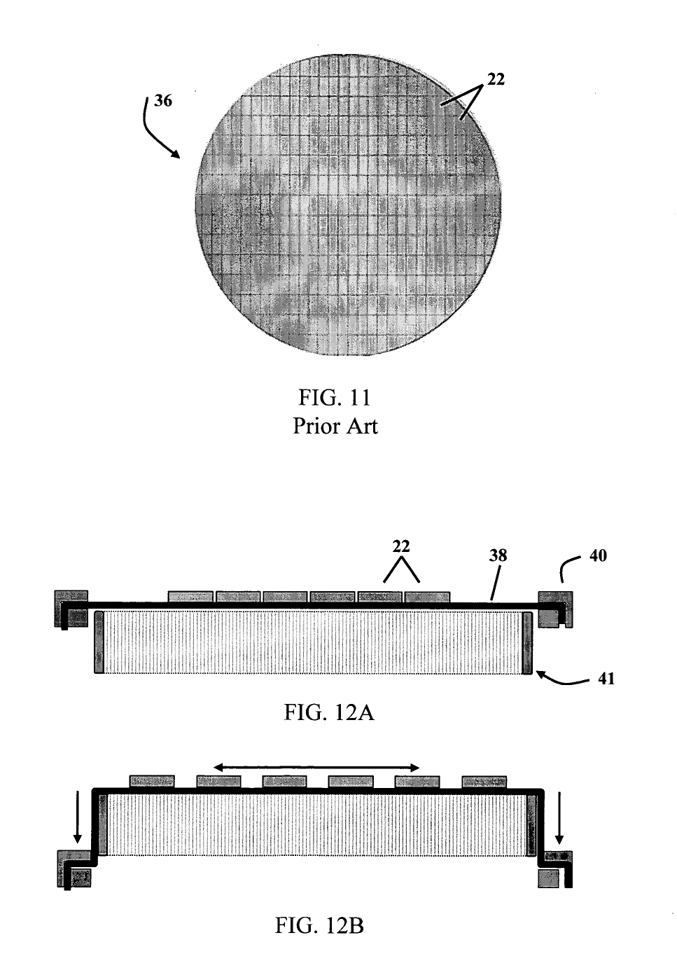

A key feature of the processes of my invention is that a wafer 36 comprised of chips can be simultaneously bonded and assembled to a substrate that can be another wafer that has different dimensions and this process will be described in detail shortly (FIG. 11). Prior art processes cannot accomplish such assembly at wafer level. Prior art requires that wafers are first singulated into individual chips and then assembled as discrete, individual components, with substantial labor, the need for expensive precision alignment bonding equipment, and the associated higher cost. I believe that the method herein disclosed provide the simplest and lowest cost methods for device packaging, multichip stacking and direct chip attachment over all prior art.

The first step in the process is to temporarily affix, or mount, a semiconductor wafer to a bondable carrier that can be an adhesively backed pliable and expandable film. The wafer can be of any type including integrated circuits, optoelectronics and electromechanical devices. This first step is commonly referred to as wafer mounting. This wafer-bonding carrier can be coated with a temporary adhesive on at least one surface, is preferably of high quality, and designed for use with semiconductors. The adhesive may be a conventional pressure-sensitive material that does not contaminate the wafer surface. The adhesive coating may also include a type that is activated by heat or by some other form of energy including photonic radiation. Adhesives are available that are deactivated with ultraviolet radiation and such materials are available in wafer mounting tape form. Furukawa UV-Tape for Wafer Dicing UC-Series is such a material and is sold by Furukawa Electric Co., Ltd. of Japan. These UV dicing tape products have near zero adhesion to chips after UV exposure, do not contaminate the chips after release, and are the preferred class for this invention.

The temporary adhesive should be pliable and capable of elongation. The adhesive may also be applied to the carrier as an array of dots, or other geometric shapes, instead of a continuous film. A discontinuous pattern of adhesive can be achieved using a screen printer, stencil printer, or ink jet dispenser, all of which are used in the electronics industry. A discontinuous pattern of adhesive can allow the carrier to be stretched and thus expanded with a minimum of mechanical stress on the attached chips. It is important that the carrier film expand in a controlled and predictable manner with a high degree of elongation when tensional force is applied to the perimeter. Conventional wafer mounting, or dicing tapes, that are generally made from polyvinyl chloride (PVC) film may not have sufficient elasticity and a material with a higher degree of elasticity is preferred. Truly elastomeric polymers, such as thermoplastic elastomer (TPE), thermoplastic urethanes (TPU), silicon rubber, and other well-known polymers, are suitable for the carrier film. It is very important for the carrier to stretch and expand evenly and in a predictable manner when the appropriate force is applied so that the resulting spacing between chips affixed to said carrier to produce spacing that is approximately equal between all chips when the substrate to be joined also has symmetrically-disposed bond sites. Conventional dicing tapes only need to be design to provide a small amount of elongation so that singulated die can be slightly separated from each other to facilitate removal of each individual die without contact on the edges of adjacent die that could cause physical damage.

The second step is to saw, or singulate, the affixed wafer. Wafer singulation is a standard well-known process that has long been used by the semiconductor industry to convert a wafer array of devices into individual chips for packaging or direct attachment to a printed circuit board or other such substrate. The affixed wafer is mounted in a standard wafer saw prior to singulation. The wafer may be held in place by gripping the carrier tape in a ring holder, or by other restraining means. The mounted wafer is than cut, or sawn through, to create individual die or chips. The most common singulation method is mechanical sawing using a diamond-coated circular metal saw blade, but other methods, such as laser singulation, are known and can be used within this invention. The cutting method is precisely controlled so that the die are carefully cut along separation zones called “streets”, so that the active chip area remains whole. The saw blade cut is maintained at the thickness of the wafer so that the carrier tape remains undamaged. It is important to note that the singulation methods do not cut, or otherwise damage, the carrier tape.

The elastomeric carrier that holds singulated chips is now ready to be stretched, or expanded, in order to provide a specific separation between individual chips that will be necessary for accurate alignment in the final bonding step to a substrate. Any method for applying evenly distributed lateral force to the perimeter of the carrier can be employed when symmetry is desired. The common ring expander, used to produce minor separation between chips that are being pulled off for packaging, is not sufficient. However, a modified ring expander mechanism may be used. This concept involves locking the perimeter of the carrier with a pair of clamping rings 40 and then applying force against the bottom of the carrier using a cylinder 41 perpendicular to the plane of the material to cause the carrier to stretch (FIGS. 12A and 12B). The cylinder may be open or closed at the top but any surfaces contacting the carrier film should have a low coefficient of friction that can be achieved by applying materials like Teflon.

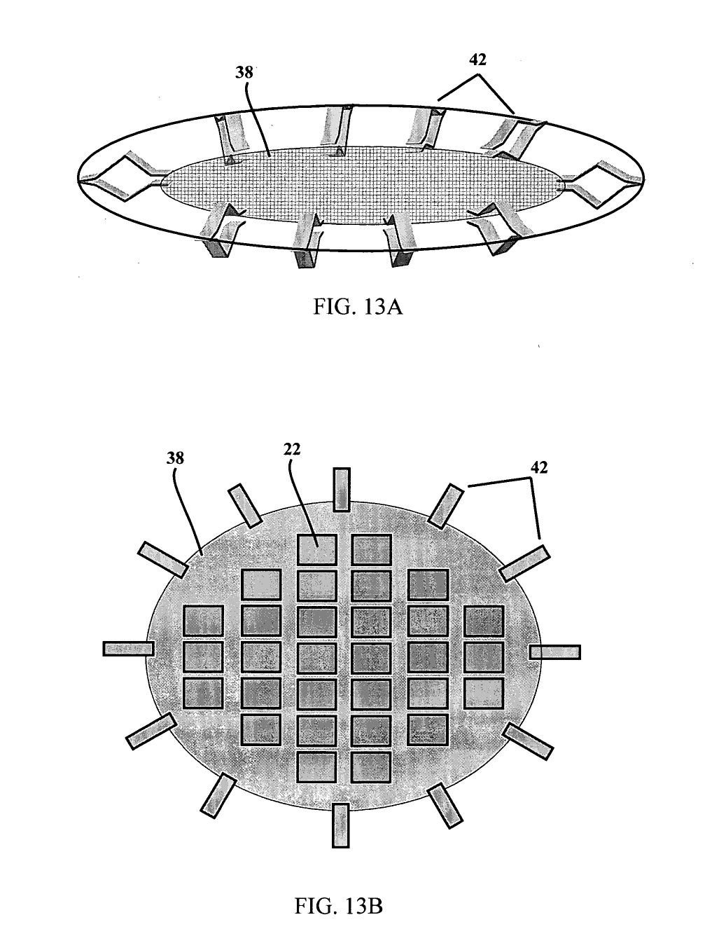

Expansion of the elastic carrier film can also be accomplished by employing an array of small edge grippers 42 disposed to clamp the edge of the film (FIGS. 13A and 13B). The array of grippers can be arranged in a circular configuration corresponding to the diameter of the carrier film (FIG. 13A). Grippers are simultaneously pulled outward, away from the center of the carrier, by pneumatic, electromagnetic, piezoelectric, or by some other mechanism and the expansion can be asymmetrical as shown (FIG. 13B). The array of grippers is moved to cause the film to elongate and expand until the spacing between chips is adequate for alignment to the selected substrate. Gripper movement can also be accomplished using precision linear drives so that chip spacing can be accurately adjusted and even controlled with a closed-loop vision system. The intent of this invention is to describe a process for wafer-level assembly and should not be limited by these examples used to describe mechanisms.

Regardless of the method for connection and expansion, the preferred process should be capable of applying a well-controlled force that will allow both symmetrical and asymmetrical expansion of the elastomeric carrier. While many applications may require symmetrical expansion to produce equidistant spacing between chips in both the x- and y-directions, it can be advantageous to have a mechanism that can independently adjust the x and x spacing as will be described later.

In the next step, the carrier having the affixed array of singulated chips is expanded to the desired level that permits said chips to be aligned and registered to a substrate that can have feature dimensions that are larger than the chips to be bonded. The expansion mechanism thus pulls the edge of elastomeric carrier to a point that permits perfect alignment with the particular substrate selected for chip bonding. The substrate can be a plurality of packages, an area array of small circuits, including RFID antennas, or another wafer that contains singulated, or unsingulated chips. In applications where the substrate has symmetrical locations for chip bonding, the carrier is expanded symmetrically. In other applications where substrate bond locations are not symmetrical, such as certain arrays of RFID antenna circuits, the elastomeric carrier 38 is expanded asymmetrically by moving x and y grippers 41 to different final displacements to provide proper spacing between chips 22 (FIG. 13B).

The next step is to join the array of chips affixed to the expanded carrier to the desired substrate. Different bonding methods can be used for various substrates that include wafers, chips, printed circuits, RFID antennas, and various types of packages. The first example describes bonding chips together to form a die stack that will be useful for efficiently manufacturing multichip packages or modules.

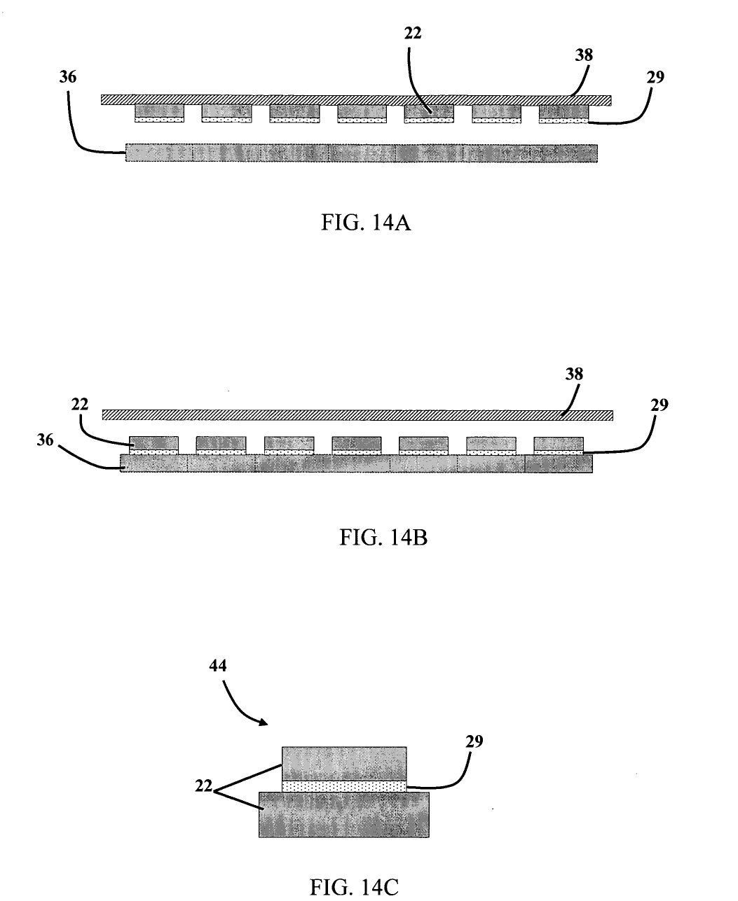

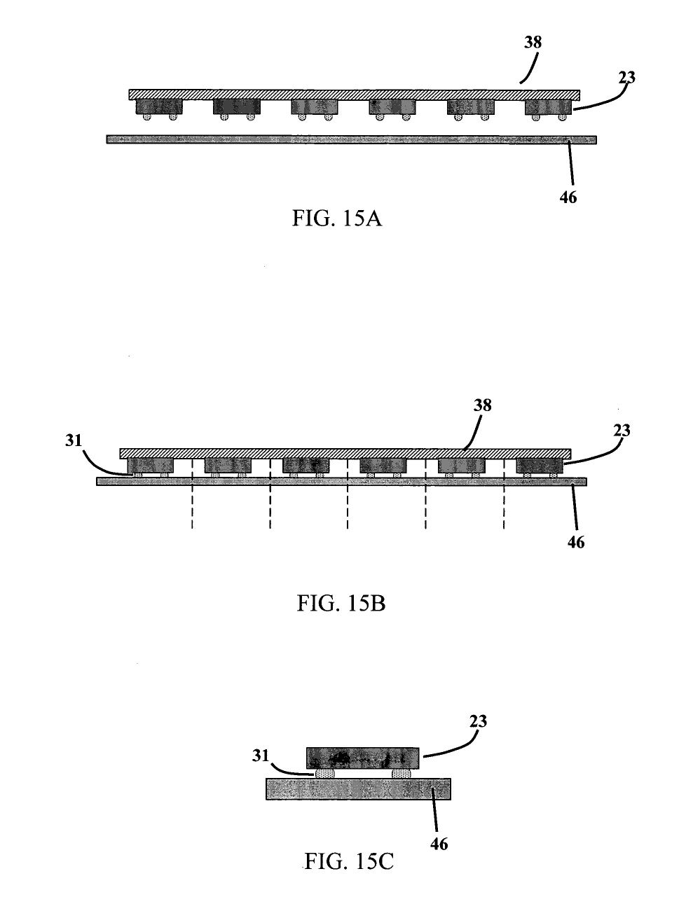

The substrate, of this example, is a wafer comprising the largest chips for the intended die stack and its chip components will become the base of the pyramid chip stack when subsequently packaged. The substrate wafer is bonded to any standard dicing tape and is referred to as substrate henceforth. The substrate may be singulated prior to bonding or after the chip stack has been assembled. The second wafer may comprise smaller chips and it is affixed to the expandable carrier previously described. The wafer is affixed to the carrier tape face down, or active side down, so that the back of the wafer is left exposed. The chips 22 are singulated using standard methods although sawing accuracy may be improved by using infrared vision to visualize chip divisions, or “streets”, that are now facing downward and obscured by the carrier 38 (FIG. 14A). The carrier is then expanded to a desired level that provides sufficient spacing between chips to allow these smaller chips to be centered and bonded to the larger substrate wafer 36. The chip array and wafer 36 are now ready to be joined (FIG. 14A). Die attach adhesive 29 can be coated onto the smaller chips, as shown, or onto the substrate using needle dispensing, printing, jetting or any other available method. The substrate and chip array are now brought in contact after alignment and the adhesive is activated (29), generally by heating (FIG. 14B). The temporary carrier is now removed leaving an array of stacked die, or individual stacks 44 if the substrate wafer was singulated as shown (FIG. 15C). The steps can be repeated with sequentially smaller die to form a higher die stack as required.

An alternate process is to apply die attach adhesive to the wafer prior to affixing to the high-expansion carrier. The wafer comprised of smaller die, may be coated on the back side with thermoplastic die attach adhesive film or paste that is available as Staystik™ from Cookson Semiconductor Packaging Materials (Cookson Electronics), Jersey City, N.J. The preferred die attach coating process entails either heat-bonding a dry thermoplastic adhesive film to the back of the wafer, or spin-coating on a solution of the material to the wafer back followed by drying in an oven. The hardened adhesive can be concurrently sawn while the chips are being singulated and this process is known within the industry and is not claimed as an invention. The coated wafer can now be bonded to the high-expansion carrier tape face down so that the backside coated with the die attach adhesive is positioned upward. The wafer can now be singulated by sawing. The carrier is expanded to provide the desired chip spacing prior to bonding as previously described. The chip array is now aligned with substrate and bonding is facilitated by applying heat to the substrate, to the chip carrier, or to both since the chips are coated with heat-activated adhesive. The carrier is next removed leaving a die stack.

While pressure-sensitive wafer tapes can be used, separation from chips by applying mechanical force subjects the assembly to mechanical stress that can damage chips or the bond between the two chips. Ultraviolet, or UV, deactivated adhesives previously described, can be used here and are preferred.

The die stacking process can be repeated with progressively smaller chips until the desired stack is achieved. Stacks of two die are commonly used but stacks of three die and even four can be used although progressively smaller die are required to form the pyramidal shape that allows access to die bonding pads on all of the chips.

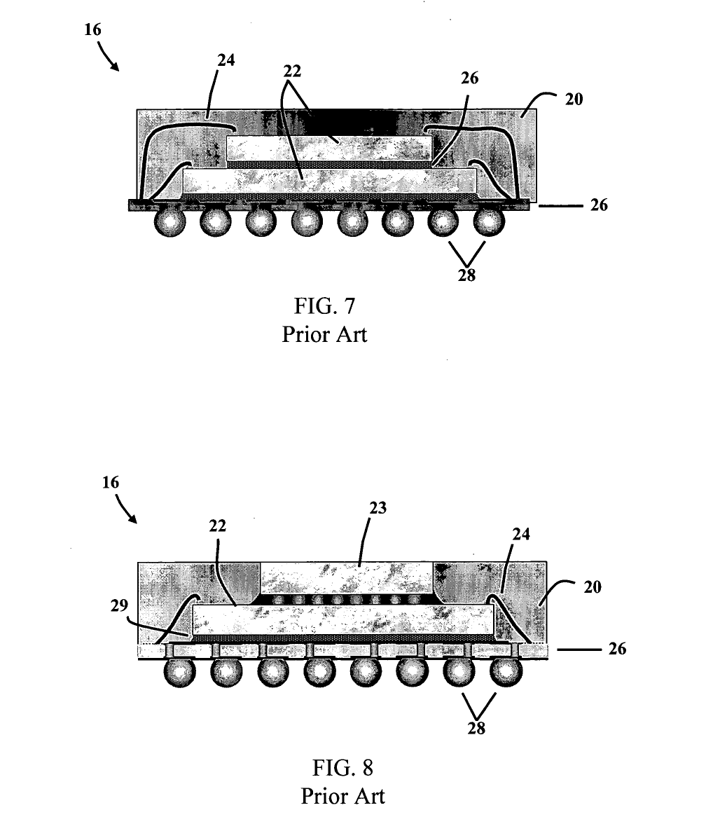

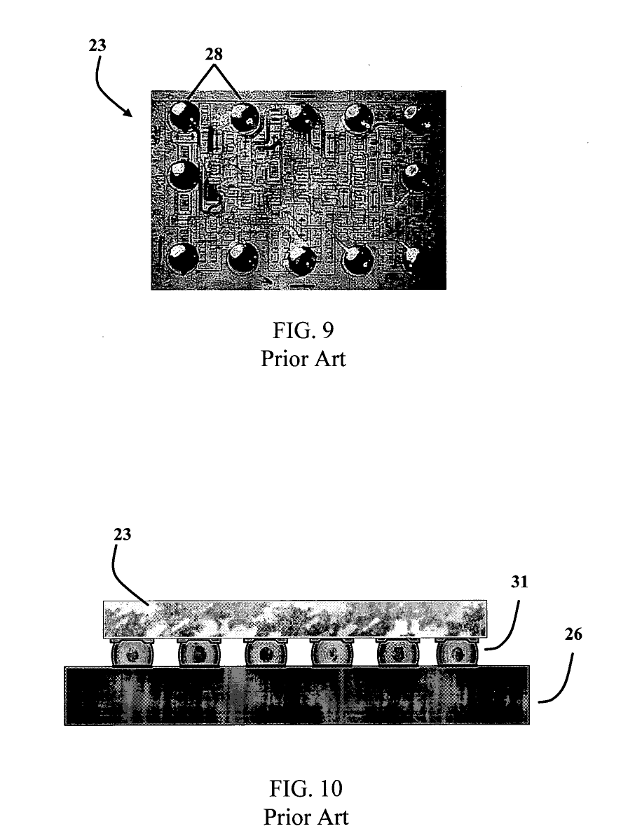

The die stack is now ready to be assembled into a package. One result of my process can be a base substrate wafer with the arrays of stacked die. It can be advantageous to leave the substrate in wafer form for shipping and handling. The substrate is now singulated, unless this was done earlier, and the individual die stacks are assembled into packages by die attachment followed by wire bonding instead of placing adhesive and die individually. The substrate wafer can be pre-coated with thermoplastic, or other heat-activated die bond adhesive as was previously described. This would permit the die stack to be attached to the package platform by simply applying heat. The final product can be a multichip package described earlier (FIG. 7).

The process can also be used to stack flip chips onto other chips in wafer form that are designed to accommodate such bonding. The flip chip wafer is temporarily affixed to the elastomeric carrier to allow singulation. The carrier 38 is then expanded by methods previously described to provide the desired spacing to produce a module after the substrate is singulated (FIG. 15A). The flip chips (23) are now ready to be bonded to a substrate suitable for assembling flip chips 46 (FIG. 15A). The flip chips (23) are brought into contact with the substrate 46 and connection joints 31 are formed by applying heat to reflow solder in the case of solder bumped chips (FIG. 15B). The process is similar for conductive adhesive assembly accept that the heat activates the adhesive to affect the bond. The final step is to singulate the substrate 46 to produce individual chip assemblies (FIG. 15C). The assemblies can be radio frequency identification tags.

The processes herein described are well suited for directly attaching chips to small printed circuit boards or any other structure with suitable electrical conductors and bonding pads. One important application is for the production of Radio Frequency Identification products, also known as RFID tags. Present methods require that the wafer is first singulated into individual chips that are subsequently bonded to the substrate that contains antenna circuit and bond pads, but may contain other structures depending on the type. However, the most common RFID, called a passive tag, is comprised of a thin dielectric with a metal, or metal composite antenna and at least two bonding pads. RFID chips are generally connected to the antenna pads by direct chip attach, or flip chip, that was described earlier. Since low cost is imperative, temperature-limited substrates are typically used. Common substrates, such as PET (polyester terephthalate), exemplified by Mylar™ (Dupont), cannot be readily soldered because of the low melting point. Therefore, the jointing material is usually a conductive adhesive. The present invention can be used to mass assemble RFID tags using all types of conductive adhesives designed for flip chip bonding.

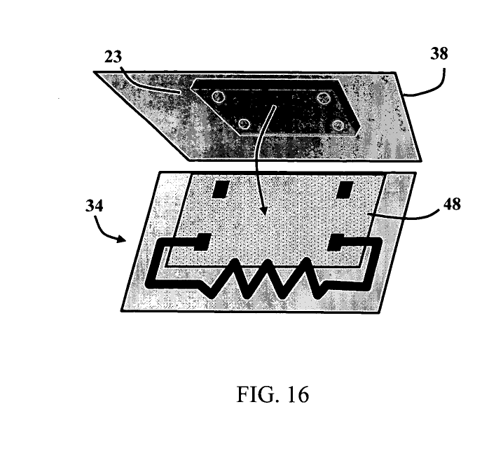

The first step is to temporarily affix the RFID wafer to the highly expandable carrier tape as described earlier. The wafer is singulated and then the carrier is expanded so that the chip spacing corresponds to bond sites on an array of RFID antenna circuits that may be produced in rolls having antennas across the web. Since the chip bond sights in the antenna array may have unequal spacing in the x and y-directions, the preferred carrier expander is capable of asymmetrical expansion as described earlier. The chip array and antenna array are ready to be bonded together but jointing material must first be applied. Alternatively, a film of adhesive can be interposed between the chips and antennas or applied to the substrate. A film of heat-activated anisotropic conductive adhesive, also known as Z-axis adhesive 48, can be placed between the aligned flip chip 23 and antenna circuit in the array 34 (FIG. 16). A single flip chip and RFID circuit is shown for simplicity. Bonding is accomplished by pressing the chip array and the RFID circuit arrays together while simultaneously heating the construction. Once the bond is formed, the temporary carrier is removed. UV deactivated adhesive is preferred so that none of the flip chips will be disturbed during film removal. Alternatively, a carrier film might be designed that can be left in place and sealed to the RFID assembly to provide protection and strength to the assembly analogous to a conformal coating used on some circuit assemblies.

My wafer-level process can also be used with conductive adhesive paste such as silver-filled epoxy that is presently used on some RFID tags. The adhesive can be applied to the bumps of the chips or to the antenna circuit pads. The chip array and antenna array are then brought together under alignment conditions, the adhesive is hardened by heating, or whatever process is required, and the wafer tape is removed or left in place as a protective film. When the adhesive is applied to the chip bumps, a simple dipping process can be used. The array of chips is dipped, or pressed against a reservoir that contains a thin film of adhesive. The reservoir can be a flat plate having a recessed channel for adhesive and a doctor blade for adhesive manipulation. The doctor blade moves across the channel prior to dipping the wafer into the reservoir of adhesive. Alternately, a rotating fluxing drum can be used, but with adhesive instead of flux. Such equipment is readily available and used for flip chip and ball grid array assembly. However, such equipment may need to be modified to accommodate a large wafer. The chip array with freshly applying adhesive is then aligned to the antenna array and bonded before removing the wafer tape, or bonding it as a protective film. Other jointing materials and application processes are known and this invention is not limited to the common ones described. These are only given as examples for the use of this invention.

This invention enables all types of chips in wafer format to be simultaneously connected to substrate for maximum manufacturing efficiency, productivity and cost-reduction. The method is well suited for very high volume applications like RFID tags. All other reported processes require that individual chips be bonded in singular fashion, one at a time. One exception is a fluidic self-alignment process used by Alien Technology, previously mentioned, where chips are fabricated with a nonsymmetrical shape to fit into a corresponding complimentary recess in the antenna circuits. While fluidic self-alignment permits more than one chip and antenna to be mated simultaneously, the method requires several additional steps that partially offset the cost savings of mass assembly. Furthermore, the special chip and antenna requirements limit the use of this method.

### EQUIVALENTS

From the foregoing detailed description of the specific embodiments of the invention, it should be apparent that a unique mass assembly process for semiconductor devices has been described. Although particular embodiments have been disclosed herein in detail, this was done by way of example for purposes of illustration only, and is not intended to be limiting with respect to the scope of appended claims which follow. In particular, it is contemplated by the inventor that various substitutions, alterations, and modifications may be made without departing from the spirit and scope of the invention defined by the claims.

What is claimed is:

1. A method for assembling integrated circuit chips to a substrate comprising the steps of:
(a) providing a wafer containing at least one integrated circuit chip, the integrated circuit chip having at least one connection site provided on at least one exposed surface thereof;
(b) affixing the wafer to an expandable carrier in a manner such that one surface is exposed;
(c) cutting the wafer in a manner which defines edges on said at least one integrated circuit chip, the cutting being of a depth which does not damage the carrier substrate;
(d) expanding the carrier in a manner which singulates said at least one integrated circuit chip, the singulation providing spacing around the integrated circuit chip;
(e) aligning said integrated circuit chip with a substrate;
(f) affixing said integrated circuit chip to a substrate;
(g) removing said carrier from the resulting assembly.

2. The method of claim 1, wherein the substrate is a wafer.

3. The method of claim 1, wherein the substrate comprises at least one printed circuit.

4. The method of claim 3 wherein the resulting assembly forms electrical interconnections.

5. The method of claim 4, wherein the resulting assembly is a Radio Frequency Identification Device, or RFID tag.

6. The method of claim 3, wherein the substrate comprises at least one flexible circuit.

8. The method of claim 1, wherein the substrate has at least one optical feature.

9. The method of claim 8, wherein the assembly forms at least one optical connection.

10. The method of claim 1, wherein the substrate is has at least one mechanical feature.

11. The method of claim 10, wherein the assembly forms at least one mechanical connection.

12. The method of claim 2, wherein the wafers are positioned with surfaces facing the same direction during assembly.

13. The method of claim 2, wherein the wafers are positioned with surfaces facing opposite directions during assembly.

14. The method of claim 2 wherein resulting assembly comprises chips with dissimilar dimensions.

15. The method of claim 1, wherein the substrate is singulated after assembly.

16. The method of claim 1, wherein the method is repeated at least once using an assembly resulting from said method as substrate.

17. The method of claim 1, wherein the wafer is comprised of flip chips.

18. The method of claim 2, wherein die attach adhesive is affixed to the backside of at least one wafer.

19. The method of claim 1, wherein an isotropically conductive adhesive substrate is positioned between the wafer and substrate prior to assembly.

20. The method of claim 1, wherein the carrier is bonded to the resulting assembly.
